(19) United States
(12) Patent Application Publication
(10) Pub. No.: US 2024/0402603 A1
(43) Pub. Date: Dec. 5, 2024

(54) PHOTOSENSITIVE RESIN COMPOSITION, PHOTOSENSITIVE ELEMENT, AND METHOD FOR PRODUCING LAYERED BODY

(71) Applicant: Resonac Corporation, Tokyo (JP)

(72) Inventors: Yusaku WATANABE, Tokyo (JP); Akiko TAKEDA, Tokyo (JP); Mao NARITA, Tokyo (JP); Keishi ONO, Tokyo (JP)

(21) Appl. No.: 18/699,058

(22) PCT Filed: Oct. 3, 2022
(86) PCT No.: PCT/JP2022/036969

§ 371 Date: May 23, 2024

(30) Foreign Application Priority Data
Oct. 7, 2021 (JP) 2021-165266

(51) Int. Cl. G03F 7/033; C08F 212/08; C08K 5/3472; C08K 5/36

(52) U.S. Cl. CPC G03F 7/033; C08F 212/08; C08K 5/3472; C08K 5/36

(57) ABSTRACT

A photosensitive resin composition containing a binder polymer, a photopolymerizable compound, a photopolymerization initiator, and a tetrazole compound, in which a content of a monomer unit of a styrene compound in the binder polymer is more than 30% by mass, and a content of the tetrazole compound is 0.01 parts by mass or more with respect to 100 parts by mass of the total of the binder polymer and the photopolymerizable compound.

### TECHNICAL FIELD

The present disclosure relates to a photosensitive resin composition, a photosensitive element, a method for producing a laminate, and the like.

### BACKGROUND ART

In the production of laminates that can be used as wiring boards, resist patterns are formed in order to obtain desired wirings. The resist pattern can be formed by exposing and developing a photosensitive resin layer obtained by using a photosensitive resin composition. As the photosensitive resin composition, various compositions have been investigated. For example, Patent Literature 1 below describes a photosensitive resin composition containing an anthracene derivative.

### CITATION LIST

### Patent Literature

Patent Literature 1: International Publication WO 2007/004619

### SUMMARY OF INVENTION

### Technical Problem

When a cured product pattern that can be used as a resist pattern is formed by using a photosensitive resin composition, a cured product pattern having a straight line area and a straight space area adjacent to the line area may be formed in some cases. In such a cured product pattern, it may be required to obtain a cured product pattern having a line area and a space area formed without defects while reducing a line width (width of the line area) in some cases.

Furthermore, according to the knowledge of the present inventors, when the line width of the cured product pattern having a line area and a space area determined to be formed without defects by microscopic observation is actually measured, a line width of a target in a drawing pattern may be deviated from an actual measured value of the line width in some cases, so that it is effective to determine the line width in the line area and the space area formed without defects based on the actual measured value. Therefore, it is required for a photosensitive resin composition for obtaining a cured product pattern to obtain a cured product pattern having a line area and a space area formed without defects while reducing an actual measured value of a line width.

An object of an aspect of the present disclosure is to provide a photosensitive resin composition with which a cured product pattern having a line area and a space area formed without defects while reducing an actual measured value of a line width can be obtained. An object of another aspect of the present disclosure is to provide a photosensitive element using this photosensitive resin composition. An object of still another aspect of the present disclosure is to provide a method for producing a laminate using the above-described photosensitive resin composition or the above-described photosensitive element.

### Solution to Problem

[1] A photosensitive resin composition containing: a binder polymer; a photopolymerizable compound; a photopolymerization initiator; and a tetrazole compound, in which a content of a monomer unit of a styrene compound in the binder polymer is more than 30% by mass, and a content of the tetrazole compound is 0.01 parts by mass or more with respect to 100 parts by mass of a total of the binder polymer and the photopolymerizable compound.

[2] The photosensitive resin composition described in [1], in which the content of the tetrazole compound is 0.01 to 1 part by mass with respect to 100 parts by mass of the total of the binder polymer and the photopolymerizable compound.

[3] The photosensitive resin composition described in [1] or [2], in which the tetrazole compound incudes 5-anmino-1H-tetrazole.

[4] The photosensitive resin composition described in any one of [1] to [3], in which the tetrazole compound includes 5-mercaptotetrazole.

[5] The photosensitive resin composition described in any one of [1] to [4], in which a weight average molecular weight of the binder polymer is 30000 to 40000.

[6] The photosensitive resin composition described in any one of [1] to [5], in which the photopolymerizable compound includes a bisphenol A-type (meth)acrylic acid compound.

[7] The photosensitive resin composition described in any one of [1] to [6], which is film-shaped.

[8] The photosensitive resin composition described in [7], in which a thickness is 30 μm or less.

[9] A photosensitive element having: a support; and a photosensitive resin layer disposed on the support, in which the photosensitive resin layer contains the photosensitive resin composition described in any one of [1] to [8].

[10] A method for producing a laminate, the method including: a step of disposing a photosensitive resin layer on a base material by using the photosensitive resin composition described in any one of [1] to [8] or the photosensitive element described in [9]; a step of photo-curing a part of the photosensitive resin layer; and a step of removing an uncured area of the photosensitive resin layer to form a cured product pattern.

### Advantageous Effects of Invention

According to an aspect of the present disclosure, it is possible to provide a photosensitive resin composition with which a cured product pattern having a line area and a space area formed without defects while reducing an actual measured value of a line width can be obtained. According to another aspect of the present disclosure, it is possible to provide a photosensitive element using this photosensitive resin composition. According to still another aspect of the present disclosure, it is possible to provide a method for producing a laminate using the above-described photosensitive resin composition or the above-described photosensitive element. According to still another aspect of the present disclosure, it is possible to provide an use of a photosensitive resin composition or a photosensitive element for forming a resist pattern. According to still another aspect of the present disclosure, it is possible to provide an use of a photosensitive resin composition or a photosensitive element for manufacturing a wiring board.

### BRIEF DESCRIPTION OF DRAWINGS

FIG. 1 is a schematic cross-sectional view illustrating an example of a photosensitive element.

FIG. 2 is a schematic view illustrating an example of a method for producing a laminate.

### DESCRIPTION OF EMBODIMENTS

Hereinafter, embodiments of the present disclosure will be described in detail.

In the present specification, a numerical range that has been indicated by use of “to” indicates the range that includes the numerical values which are described before and after “to”, as the minimum value and the maximum value, respectively. The numerical range “A or more” means A and a range of more than A. The numerical range “A or less” means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In a numerical range described in the present specification, the upper limit value or the lower limit value of the numerical range may be substituted by a value shown in Examples. “A or B” may include either one of A and B, and may also include both of A and B. Materials listed as examples in the present specification can be used singly or in combinations of two or more kinds, unless otherwise specified. When a plurality of substances corresponding to each component exist in the composition, the content of each component in the composition means the total amount of the plurality of substances that exist in the composition, unless otherwise specified. The term “layer” includes a structure having a shape which is formed on a part, in addition to a structure having a shape which is formed on the whole surface, when the layer has been observed as a plan view. The term “step” includes not only an independent step but also a step by which an intended action of the step is achieved, even though the step cannot be clearly distinguished from other steps. The term “(meth)acrylate” means at least one of “acrylate” and “methacrylate” corresponding thereto. The same applies to other analogous expressions such as “(meth)acrylic acid”. The phrase “the content of the monomer unit of (meth)acrylic acid” means the total amount of the monomer unit of acrylic acid and the monomer unit of methacrylic acid, and the same applies to other analogous expressions. The “alkyl group” may be linear, branched, or cyclic, unless otherwise specified.

In the present specification, the term “EO-modified” means a compound having a (poly)oxyethylene group. The term “PO-modified” means a compound having a (poly)oxypropylene group. The term “EO/PO-modified” means a compound having a (poly)oxyethylene group and a (poly)oxypropylene group. The term “(poly)oxyethylene group” means at least one of an oxyethylene group and a polyoxyethylene group (a group in which two or more ethylene groups are linked via an ether bond). The same applies to other analogous expressions such as “(poly)oxypropylene group”.

In the present specification, the phrase “the solid content of a photosensitive resin composition” refers to a non-volatile content of a photosensitive resin composition excluding volatile substances (such as water and an organic solvent). That is, the term “solid content” refers to components remaining without volatile in drying of the photosensitive resin composition and also encompasses components in a liquid, a syrupy state, a waxy state, and the like at room temperature (25° C.).

### <Photosensitive Resin Composition and Cured Product>

A photosensitive resin composition of the present embodiment contains (A) a binder polymer (component (A)), (B) a photopolymerizable compound (component (B)), (C) a photopolymerization initiator (component (C)), and (D) a tetrazole compound (component (D)), in which a content of a monomer unit of a styrene compound in the component (A) is more than 30% by mass, and a content of the component (D) is 0.01 parts by mass or more with respect to 100 parts by mass of the total of the component (A) and the component (B). The photosensitive resin composition of the present embodiment can be used, for example, as a negative photosensitive resin composition. The photosensitive resin composition of the present embodiment may be in a liquid form and may be film-shaped (photosensitive film).

The photosensitive resin composition of the present embodiment has photo-curability and a cured product can be obtained by photo-curing this photosensitive resin composition. A cured product of the present embodiment is a cured product (photo-cured product) of the photosensitive resin composition of the present embodiment. The cured product of the present embodiment may have a patterned shape (cured product pattern), and may be a resist pattern.

The thickness of the film-shaped photosensitive resin composition or the thickness of the cured product may be 1 μm or more, 5 μm or more, 10 μm or more, 15 μm or more, 20 m or more, or 25 μm or more. The thickness of the film-shaped photosensitive resin composition or the thickness of the cured product may be 100 μm or less, 50 μm or less, 40 μm or less, 30 μm or less, or 25 μm or less. From these viewpoints, the thickness of the film-shaped photosensitive resin composition or the thickness of the cured product may be 1 to 100 μm.

According to the photosensitive resin composition of the present embodiment, a cured product pattern having a line area and a space area formed without defects while reducing an actual measured value of a line width (a cured product pattern excellent in adhesiveness: for example, a cured product pattern formed on a metal copper layer) can be obtained. As for factors for obtaining such an effect, the present inventors have speculated that the component (D), which has a plurality of nitrogen atoms in the ring, chemically (such as hydrogen bond or coordination bond) or physically assists the adhesion between a base material and a resin component of the cured product, so that the above-described effect is obtained. However, the factors are not limited to the contents.

According to the photosensitive resin composition of the present embodiment, in the case of forming a cured product pattern in which a line width is smaller than a space width, a cured product pattern having a line area and a space area formed without defects while reducing an actual measured value of a line width can be obtained. According to the photosensitive resin composition of the present embodiment, in the evaluation method described in Examples described below, an actual measured value of a line width in a cured product pattern in which space areas (unexposed areas) are removed without residues and line areas are formed without meandering and chipping after development can be reduced to 7.00 μm or less.

The photosensitive resin composition of the present embodiment contains a binder polymer (excluding a compound corresponding to a tetrazole compound) as the component (A). Examples of the component (A) include an acrylic resin, a styrene-based resin, an epoxy-based resin, an amide-based resin, an amide-epoxy-based resin, an alkyd-based resin, and a phenol-based resin. The acrylic resin is a resin that has a compound having a (meth)acryloyl group ((meth)acrylic acid compound) as a monomer unit, and a styrene-based resin, an epoxy-based resin, an amide-based resin, an amide-epoxy-based resin, an alkyd-based resin, and a phenol-based resin that have this monomer unit attribute to the acrylic resin.

The component (A) may include an acrylic resin from the viewpoint of easily reducing an actual measured value of a line width. The content of the acrylic resin may be 50% by mass or more, more than 50% by mass, 70% by mass or more, 90% by mass or more, 95% by mass or more, 98% by mass or more, 99% by mass or more, or substantially 100% by mass (an embodiment in which the component (A) is substantially composed of the acrylic resin), on the basis of the total mass of the component (A), from the viewpoint of easily reducing an actual measured value of a line width.

Examples of the compound having a (meth)acryloyl group include a (meth)acrylic acid and a (meth)acrylic acid ester. Examples of the (meth)acrylic acid ester include alkyl (meth)acrylate (alkyl (meth)acrylate ester; excluding a compound corresponding to cycloalkyl (meth)acrylate), cycloalkyl (meth)acrylate (cycloalkyl (meth)acrylate ester), aryl (meth)acrylate (aryl (meth)acrylate ester), a (meth)acrylamide compound (such as diacetone acrylamide), glycidyl (meth)acrylate ester, and styryl (meth)acrylate.

The component (A) may have a (meth)acrylic acid as a monomer unit from the viewpoint of easily reducing an actual measured value of a line width.

In a case where the component (A) has a (meth)acrylic acid as a monomer unit, the content of the monomer unit of the (meth)acrylic acid may be in the following range on the basis of the total amount of monomer units constituting the component (A), from the viewpoint of easily reducing an actual measured value of a line width. The content of the monomer unit of the (meth)acrylic acid may be 1% by mass or more, 5% by mass or more, 10% by mass or more, 15% by mass or more, 20% by mass or more, 25% by mass or more, or 27% by mass or more. The content of the monomer unit of the (meth)acrylic acid may be 50% by mass or less, less than 50% by mass, 45% by mass or less, 40% by mass or less, 35% by mass or less, 30% by mass or less, or 27% by mass or less. From these viewpoints, the content of the monomer unit of the (meth)acrylic acid may be 1 to 50% by mass.

The component (A) may have alkyl (meth)acrylate as a monomer unit from the viewpoint of easily reducing an actual measured value of a line width. Examples of the alkyl group of the alkyl (meth)acrylate include a methyl group, an ethyl group, a propyl group, a butyl group, a pentyl group, a hexyl group, a heptyl group, an octyl group, a nonyl group, a decyl group, an undecyl group, and a dodecyl group, and the alkyl group may be various structural isomers. The number of carbon atoms of the alkyl group of the alkyl (meth)acrylate may be 1 to 4, 1 to 3, 2 to 3, or 1 to 2, from the viewpoint of easily reducing an actual measured value of a line width.

The alkyl group of the alkyl (meth)acrylate may have a substituent. Examples of the substituent include a hydroxy group, an amino group, an epoxy group, a furyl group, and a halogeno group (such as a fluoro group, a chloro group, and a bromo group). Examples of the alkyl (meth)acrylate include hydroxyalkyl (meth)acrylate, dimethylaminoethyl (meth)acrylate, diethylaminoethyl (meth)acrylate, 2,2,2-trifluoroethyl (meth)acrylate, 2,2,3,3-tetrafluoropropyl (meth)acrylate, α-chloro (meth)acrylic acid, and α-bromo (meth)acrylic acid.

The component (A) may have hydroxyalkyl (meth)acrylate as a monomer unit from the viewpoint of easily reducing an actual measured value of a line width. Examples of the hydroxyalkyl (meth)acrylate include hydroxymethyl (meth)acrylate, hydroxyethyl (meth)acrylate, hydroxypropyl (meth)acrylate, hydroxybutyl (meth) acrylate, hydroxypentyl (meth)acrylate, and hydroxyhexyl (meth)acrylate.

The content of the monomer unit of alkyl (meth)acrylate in a case where the component (A) has alkyl (meth)acrylate as a monomer unit or the content of the monomer unit of hydroxyalkyl (meth)acrylate in a case where the component (A) has hydroxyalkyl (meth)acrylate as a monomer unit may be in the following range on the basis of the total amount of monomer units constituting the component (A), from the viewpoint of easily reducing an actual measured value of a line width. The content of the above-described monomer unit may be 0.1% by mass or more, 0.5% by mass or more, 1% by mass or more, 2% by mass or more, or 3% by mass or more. The content of the above-described monomer unit may be 20% by mass or less, 15% by mass or less, 10% by mass or less, 8% by mass or less, 5% by mass or less, or 3% by mass or less. From these viewpoints, the content of the above-described monomer unit may be 0.1 to 20% by mass.

The component (A) may have aryl (meth)acrylate as a monomer unit from the viewpoint of easily reducing an actual measured value of a line width. Examples of the aryl (meth)acrylate include benzyl (meth)acrylate, phenyl (meth)acrylate, and naphthyl (meth)acrylate.

In a case where the component (A) has aryl (meth)acrylate as a monomer unit, the content of the monomer unit of the aryl (meth)acrylate may be in the following range on the basis of the total amount of monomer units constituting the component (A), from the viewpoint of easily reducing an actual measured value of a line width. The content of the monomer unit of the aryl (meth)acrylate may be 1% by mass or more, 5% by mass or more, 10% by mass or more, 15% by mass or more, or 20% by mass or more. The content of the monomer unit of the aryl (meth)acrylate may be 50% by mass or less, less than 50% by mass, 45% by mass or less, 40% by mass or less, 35% by mass or less, 30% by mass or less, 25% by mass or less, or 20% by mass or less. From these viewpoints, the content of the monomer unit of the aryl (meth)acrylate may be 1 to 50% by mass.

The component (A) has a styrene compound as a monomer unit. Examples of the styrene compound include styrene and a styrene derivative. Examples of the styrene derivative include vinyl toluene and Y-methylstyrene. The component (A) may have hydroxyalkyl (meth)acrylate and a styrene compound as monomer units from the viewpoint of easily reducing an actual measured value of a line width.

The content of the monomer unit of the styrene compound is more than 30% by mass on the basis of the total amount of monomer units constituting the component (A), and may be in the following range from the viewpoint of easily reducing an actual measured value of a line width. The content of the monomer unit of the styrene compound may be 32% by mass or more, 35% by mass or more, 40% by mass or more, 45% by mass or more, 47% by mass or more, or 50% by mass or more. The content of the monomer unit of the styrene compound may be 90% by mass or less, 85% by mass or less, 80% by mass or less, 75% by mass or less, 70% by mass or less, 65% by mass or less, 60% by mass or less, 55% by mass or less, or 50% by mass or less. From these viewpoints, the content of the monomer unit of the styrene compound may be more than 30% by mass and 90% by mass or less.

The component (A) may have other monomer as a monomer unit. Examples of such a monomer include ethers of vinyl alcohol (such as vinyl-n-butyl ether), (meth)acrylonitrile, maleic acid, maleic anhydride, maleic acid monoesters (such as monomethyl maleate, monoethyl maleate, and monoisopropyl maleate), fumaric acid, cinnamic acid, α-cyanocinnamic acid, itaconic acid, crotonic acid, and propiolic acid.

The acid value of the component (A) may be in the following range from the viewpoint of easily reducing an actual measured value of a line width. The acid value of the component (A) may be 80 mgKOH/g or more, 90 mgKOH/g or more, 100 mgKOH/g or more, more than 100 mgKOH/g, 120 mgKOH/g or more, 140 mgKOH/g or more, 150 mgKOH/g or more, 160 mgKOH/g or more, or 170 mgKOH/g or more. The acid value of the component (A) may be 250 mgKOH/g or less, 240 mgKOH/g or less, 230 mgKOH/g or less, 210 mgKOH/g or less, 200 mgKOH/g or less, or 180 mgKOH/g or less. From these viewpoints, the acid value of the component (A) may be 80 to 250 mgKOH/g. The acid value of the component (A) can be adjusted by the content of monomer units (for example, the monomer unit of the (meth)acrylic acid) constituting the component (A). The acid value of the component (A) can be measured by the method described in Examples. In a case where a solution obtained by mixing the component (A) with volatile components such as a synthetic solvent or a diluent solvent is used as a measurement target, the acid value can be calculated by the formula below. In a case where the component (A) is blended in a state of being mixed with volatile components such as a synthetic solvent or a diluent solvent, the acid value can also be measured after removing the volatile components by heating for 1 to 4 hours at a temperature higher than the boiling point of the volatile components by 10° C. or more in advance before precise weighing.

Acid value=0.1×Vf×56.1/(Wp×I/100)

[In the formula, Vf represents the titer (unit: mL) of a KOH (potassium hydroxide) aqueous solution, Wp represents the mass (unit: g) of the solution containing the component (A) as a measurement target, and I represents the proportion (unit: % by mass) of non-volatile content in the solution containing the component (A) as a measurement target.]

The weight average molecular weight (Mw) of the component (A) may be in the following range from the viewpoint of easily reducing an actual measured value of a line width. The weight average molecular weight of the component (A) may be 10000 or more, 20000 or more, 25000 or more, 30000 or more, or 35000 or more. The weight average molecular weight of the component (A) may be 100000 or less, 80000 or less, 70000 or less, less than 70000, 65000 or less, 60000 or less, 50000 or less, 40000 or less, or 35000 or less. From these viewpoints, the weight average molecular weight of the component (A) may be 10000 to 100000, 20000 to 50000, or 30000 to 40000.

The number average molecular weight (Mn) of the component (A) may be in the following range from the viewpoint of easily reducing an actual measured value of a line width. The number average molecular weight of the component (A) may be 5000 or more, 10000 or more, 12000 or more, 15000 or more, or 16000 or more. The number average molecular weight of the component (A) may be 50000 or less, 40000 or less, 35000 or less, 30000 or less, 25000 or less, 20000 or less, or 16000 or less. From these viewpoints, the number average molecular weight of the component (A) may be 5000 to 50000, 10000 to 25000, or 15000 to 20000.

The degree of dispersion (weight average molecular weight/number average molecular weight) of the component (A) may be in the following range from the viewpoint of easily reducing an actual measured value of a line width. The degree of dispersion of the component (A) may be 1.0 or more, 1.5 or more, 1.8 or more, 2.0 or more, or 2.1 or more. The degree of dispersion of the component (A) may be 3.0 or less, 2.8 or less, 2.5 or less, 2.3 or less, or 2.2 or less. From these viewpoints, the degree of dispersion of the component (A) may be 1.0 to 3.0.

The weight average molecular weight and the number average molecular weight can be measured, for example, by gel permeation chromatography (GPC) using a calibration curve of standard polystyrene. More specifically, it is possible to measure under conditions described in Examples. As for a compound having a low molecular weight, in a case where measurement of the weight average molecular weight and the number average molecular weight is difficult using the above-described measurement method, it is also possible to measure the molecular weights using other methods and to calculate an average value thereof.

The content of the component (A) may be in the following range on the basis of the total amount of solid contents of the photosensitive resin composition from the viewpoint of easily reducing an actual measured value of a line width. The content of the component (A) may be 10% by mass or more, 20% by mass or more, 30% by mass or more, 40% by mass or more, 45% by mass or more, or 50% by mass or more, from the viewpoint of excellent film moldability. The content of the component (A) may be 90% by mass or less, 80% by mass or less, 75% by mass or less, 70% by mass or less, 65% by mass or less, 60% by mass or less, or 55% by mass or less. From these viewpoints, the content of the component (A) may be 10 to 90% by mass.

The content of the component (A) may be in the following range with respect to 100 parts by mass of the total amount of the component (A) and the component (B) from the viewpoint of easily reducing an actual measured value of a line width. The content of the component (A) may be 10 parts by mass or more, 20 parts by mass or more, 30 parts by mass or more, 40 parts by mass or more, 45 parts by mass or more, 50 parts by mass or more, or 55 parts by mass or more, from the viewpoint of excellent film moldability. The content of the component (A) may be 90 parts by mass or less, 80 parts by mass or less, 75 parts by mass or less, 70 parts by mass or less, 65 parts by mass or less, or 60 parts by mass or less. From these viewpoints, the content of the component (A) may be 10 to 90 parts by mass.

The photosensitive resin composition of the present embodiment contains a photopolymerizable compound (excluding a compound corresponding to a tetrazole compound) as the component (B). The photopolymerizable compound is a compound that is polymerized with light, and may be, for example, a compound having an ethylenically unsaturated bond.

Examples of the component (B) include a bisphenol A-type (meth)acrylic acid compound, EO-modified di(meth)acrylate, PO-modified di(meth)acrylate, FO/PO-modified di(meth)acrylate, polyalkylene glycol di(meth)acrylate (such as polyethylene glycol di(meth)acrylate and polypropylene glycol di(meth)acrylate), EO-modified polyalkylene glycol di(meth)acrylate, PO-modified polyalkylene glycol di(meth)acrylate, EO/PO-modified polyalkylene glycol di(meth)acrylate, trimethylol propane di(meth)acrylate, trimethylol propane tri(meth)acrylate, EO-modified trimethylol propane tri(meth)acrylate, PO-modified trimethylol propane tri(meth)acrylate, EO/PO-modified trimethylol propane tri(meth)acrylate, a compound having a ditrimethylol propane skeleton, tetramethylolmethane tri(meth)acrylate, tetramethylolmethane tetra(meth)acrylate, EO-modified pentaerythritol tetra(meth)acrylate, PO-modified pentaerythritol tetra(meth)acrylate, EO/PO-modified pentaerythritol tetra(meth)acrylate, EO-modified dipentaerythritol hexa(meth)acrylate, PO-modified dipentaerythritol hexa(meth)acrylate, EO/PO-modified dipentaerythritol hexa(meth)acrylate, nonylphenoxypolyethylene oxyacrylate, a phthalic acid-based compound, alkyl (meth)acrylate, and a photopolymerizable compound having at least one cationic polymerizable cyclic ether group in the molecule (such as an oxetane compound).

The component (B) may include a bisphenol A-type (meth)acrylic acid compound from the viewpoint of easily reducing an actual measured value of a line width. Examples of the bisphenol A-type (meth)acrylic acid compound include 2,2-bis(4-((meth)acryloxypolyethoxy)phenyl)propane (such as 2,2-bis(4-((meth)acryloxypentaethoxy)phenyl)propane), 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane. From the viewpoint of easily reducing an actual measured value of a line width, the component (B) may include 2,2-bis(4-((meth)acryloxypolyethoxy)phenyl)propane, and may include 2,2-bis(4-((meth)acryloxypentaethoxy)phenyl)propane.

The content of the bisphenol A-type (meth)acrylic acid compound is 100% by mass or less on the basis of the total mass of the component (B), and may be in the following range from the viewpoint of easily reducing an actual measured value of a line width. The content of the bisphenol A-type (meth)acrylic acid compound may be 50% by mass or more, more than 50% by mass, 60% by mass or more, 70% by mass or more, 75% by mass or more, 80% by mass or more, 85% by mass or more, or 90% by mass or more. The content of the bisphenol A-type (meth)acrylic acid compound may be less than 100% by mass, 99% by mass or less, 98% by mass or less, 97% by mass or less, 95% by mass or less, 92% by mass or less, or 91% by mass or less. From these viewpoints, the content of the bisphenol A-type (meth)acrylic acid compound may be 50 to 100% by mass.

The content of the bisphenol A-type (meth)acrylic acid compound may be in the following range on the basis of the total amount of solid contents of the photosensitive resin composition from the viewpoint of easily reducing an actual measured value of a line width. The content of the bisphenol A-type (meth)acrylic acid compound may be 1% by mass or more, 5% by mass or more, 10% by mass or more, 15% by mass or more, 20% by mass or more, 25% by mass or more, 30% by mass or more, or 35% by mass or more. The content of the bisphenol A-type (meth)acrylic acid compound may be 90% by mass or less, 80% by mass or less, 70% by mass or less, 65% by mass or less, 60% by mass or less, 55% by mass or less, 50% by mass or less, 45% by mass or less, or 40% by mass or less. From these viewpoints, the content of the bisphenol A-type (meth)acrylic acid compound may be 1 to 90% by mass.

The content of the bisphenol A-type (meth)acrylic acid compound may be in the following range with respect to 100 parts by mass of the total amount of the component (A) and the component (B) from the viewpoint of easily reducing an actual measured value of a line width. The content of the bisphenol A-type (meth)acrylic acid compound may be 1 part by mass or more, 5 parts by mass or more, 10 parts by mass or more, 15 parts by mass or more, 20 parts by mass or more, 25 parts by mass or more, 30 parts by mass or more, 32 parts by mass or more, 35 parts by mass or more, 38 parts by mass or more, or 40 parts by mass or more. The content of the bisphenol A-type (meth)acrylic acid compound may be 90 parts by mass or less, 80 parts by mass or less, 70 parts by mass or less, 60 parts by mass or less, 50 parts by mass or less, 45 parts by mass or less, or 40 parts by mass or less. From these viewpoints, the content of the bisphenol A-type (meth)acrylic acid compound may be 1 to 90 parts by mass.

The content of the component (B) may be in the following range on the basis of the total amount of solid contents of the photosensitive resin composition from the viewpoint of easily reducing an actual measured value of a line width. The content of the component (B) may be 10% by mass or more, 15% by mass or more, 20% by mass or more, 25% by mass or more, 30% by mass or more, 35% by mass or more, or 40% by mass or more. The content of the component (B) may be 90% by mass or less, 80% by mass or less, 70% by mass or less, 65% by mass or less, 60% by mass or less, 55% by mass or less, 50% by mass or less, or 45% by mass or less. From these viewpoints, the content of the component (B) may be 10 to 90% by mass.

The content of the component (B) may be in the following range with respect to 100 parts by mass of the total amount of the component (A) and the component (B) from the viewpoint of easily reducing an actual measured value of a line width. The content of the component (B) may be 10 parts by mass or more, 20 parts by mass or more, 25 parts by mass or more, 30 parts by mass or more, 35 parts by mass or more, or 40 parts by mass or more. The content of the component (B) may be 90 parts by mass or less, 80 parts by mass or less, 70 parts by mass or less, 60 parts by mass or less, 55 parts by mass or less, 50 parts by mass or less, or 45 parts by mass or less. From these viewpoints, the content of the component (B) may be 10 to 90 parts by mass.

The photosensitive resin composition of the present embodiment contains a photopolymerization initiator (excluding a compound corresponding to a tetrazole compound) as the component (C).

Examples of the component (C) include a hexaarylbiimidazole compound; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinone compounds such as alkylanthraquinone; benzoinether compounds such as benzoinalkyl ethers; benzoin compounds such as benzoin and alkylbenzoin; benzyl derivatives such as benzyldimethylketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The component (C) may include a hexaarylbiimidazole compound from the viewpoint of easily reducing an actual measured value of a line width. The aryl group in the hexaarylbiimidazole compound may be a phenyl group or the like. A hydrogen atom bonded to the aryl group in the hexaarylbiimidazole compound may be substituted with a halogen atom (a chlorine atom or the like).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer. The hexaarylbiimidazole compound may include a 2-(o-chlorophenyl)-4,5-diphenylimidazole dimer, and may include 2,2′T-bis(o-chlorophenyl)-4,4′,5,5′-tetraphenyl-1,2′-biimidazole, from the viewpoint of easily reducing an actual measured value of a line width.

The content of the hexaarylbiimidazole compound may be 50% by mass or more, more than 50% by mass, 70% by mass or more, 90% by mass or more, 95% by mass or more, 98% by mass or more, 99% by mass or more, or substantially 100% by mass (an embodiment in which the component (C) is substantially composed of the hexaarylbiimidazole compound), on the basis of the total amount of the component (C), from the viewpoint of easily reducing an actual measured value of a line width.

The content of the component (C) may be in the following range on the basis of the total amount of solid contents of the photosensitive resin composition from the viewpoint of easily reducing an actual measured value of a line width. The content of the component (C) may be 0.12% by mass or more, 0.5% by mass or more, 1% by mass or more, 2% by mass or more, 3% by mass or more, 4% by mass or more, 5% by mass or more, or 5.5% by mass or more. The content of the component (C) may be 20% by mass or less, 15% by mass or less, 12% by mass or less, 10% by mass or less, 8% by mass or less, 7% by mass or less, or 6% by mass or less. From these viewpoints, the content of the component (C) may be 0.1 to 20% by mass.

The content of the component (C) may be in the following range with respect to 100 parts by mass of the total amount of the component (A) and the component (B), from the viewpoint of easily reducing an actual measured value of a line width. The content of the component (C) may be 0.1 parts by mass or more, 0.5 parts by mass or more, 1 part by mass or more, 2 parts by mass or more, 3 parts by mass or more, 4 parts by mass or more, 5 parts by mass or more, 5.5 parts by mass or more, or 6 parts by mass or more. The content of the component (C) may be 20 parts by mass or less, 15 parts by mass or less, 12 parts by mass or less, 10 parts by mass or less, 8 parts by mass or less, 7 parts by mass or less, or 6 parts by mass or less. From these viewpoints, the content of the component (C) may be 0.1 to 20 parts by mass.

The photosensitive resin composition of the present embodiment contains a tetrazole compound (a compound having a tetrazole ring) as the component (D). As the component (D), a compound represented by General Formula (1) below can be used.

### [Chemical Formula 1]

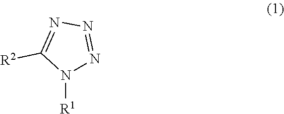

[In Formula (1), R¹ and R² each independently represent a hydrogen atom, an alkyl group (substituted or unsubstituted alkyl group; excluding a cycloalkyl group), a cycloalkyl group (substituted or unsubstituted cycloalkyl group), a phenyl group (substituted or unsubstituted phenyl group), an amino group, a mercapto group, or a benzoyl group. R¹ and R² may be bonded to each other to form a cyclic structure.]

The number of carbon atoms of the alkyl group may be 1 to 20, 1 to 16, 1 to 12, 1 to 8, 1 to 6, 1 to 4, 1 to 3, or 1 to 2. The number of carbon atoms of the cycloalkyl group may be 3 to 10 or 3 to 6. Examples of substituents of the alkyl group and the cycloalkyl group include a halogeno group (for example, a fluoro group), an amino group, a monoalkylamino group, a dialkylamino group, a mercapto group, a carboxy group, a carboxylate group, a hydroxy group, an alkoxy group, and an aldehyde group. Examples of substituents of the phenyl group include an alkyl group, a halogeno group (for example, a fluoro group), an amino group, a monoalkylamino group, a dialkylamino group, a mercapto group, a carboxy group, a carboxylate group, a hydroxy group, an alkoxy group, and an aldehyde group.

Examples of the component (D) include 1H-tetrazole, 5-anmino-1H-tetrazole, 5-methyl-H-tetrazole, 5-(2-aminophenyl)-1H-tetrazole, 5-phenyl-1H-tetrazole, 5-mercapto-1H-tetrazole, 1-methyl-5-ethyltetrazole, 1-methyl-5-aminotetrazole, 1-methyl-5-mercaptotetrazole, 1-methyl-5-benzoyl-1H-tetrazole, 1-carboxymethyl-5-amino-tetrazole, 1-cyclohexyl-5-mercaptotetrazole, 1-phenyltetrazole, 1-phenyl-5-mercaptotetrazole, 1-carboxymethyl-5-mercaptotetrazole, 1,5-pentamethylenetetrazole, 1-(2-dimethylaminoethyl)-5-mercaptotetrazole, and 2-methoxy-5-(5-trifluoromethyl-1H-tetrazole-1-yl)-benzaldehyde. The component (D) may include at least one selected from the group consisting of 5-amino-1H-tetrazole and 5-mercaptotetrazole from the viewpoint of easily reducing an actual measured value of a line width. That is, the component (D) may be an embodiment including 5-amino-1H-tetrazole, and may be an embodiment including 5-mercaptotetrazole.

The content of the component (D) may be in the following range on the basis of the total amount of solid contents of the photosensitive resin composition from the viewpoint of easily reducing an actual measured value of a line width. The content of the component (D) may be 0.01% by mass or more, 0.05% by mass or more, 0.1% by mass or more, 0.15% by mass or more, 0.2% by mass or more, 0.25% by mass or more, 0.3% by mass or more, 0.35% by mass or more, 0.4% by mass or more, or 0.45% by mass or more. The content of the component (D) may be 5% by mass or less, 3% by mass or less, 1% by mass or less, 0.9% by mass or less, 0.8% by mass or less, 0.7% by mass or less, 0.6% by mass or less, 0.55% by mass or less, or 0.5% by mass or less. From these viewpoints, the content of the component (D) may be 0.01 to 5% by mass.

The content of the component (D) may be in the following range with respect to 100 parts by mass of the total amount of the component (A) and the component (B) from the viewpoint of easily reducing an actual measured value of a line width. The content of the component (D) may be 0.01 parts by mass or more, 0.05 parts by mass or more, 0.1 parts by mass or more, 0.15 parts by mass or more, 0.2 parts by mass or more, 0.25 parts by mass or more, 0.3 parts by mass or more, 0.35 parts by mass or more, 0.4 parts by mass or more, 0.45 parts by mass or more, or 0.5 parts by mass or more. The content of the component (D) may be 5 parts by mass or less, 3 parts by mass or less, 1 part by mass or less, 0.9 parts by mass or less, 0.8 parts by mass or less, 0.7 parts by mass or less, 0.6 parts by mass or less, 0.55 parts by mass or less, or 0.5 parts by mass or less. From these viewpoints, the content of the component (D) may be 0.01 to 5 parts by mass or 0.01 to 1 part by mass.

The photosensitive resin composition of the present embodiment may contain other component (excluding a compound corresponding to the component (A), the component (B), the component (C), or the component (D)). Examples of the other component include hydrogen donors, an anthracene compound, polymerization inhibitors, organic solvents, dyes (such as malachite green), photosensitizers (excluding an anthracene compound), tribromophenylsulfone, photochromic agents, thermal development inhibitors, plasticizers (such as p-toluenesulfonamide), pigments, fillers, antifoaming agents, flame retardants, stabilizers (such as light stabilizers), tackifiers, leveling agents, release promoters, antioxidants, aromatics, imaging agents, and thermal crosslinking agents.

Examples of the hydrogen donor include bis[4-(dimethylamino)phenyl]methane, bis[4-(diethylamino)phenyl]methane, leuco crystal violet, and N-phenylglycine.

The content of the hydrogen donor may be in the following range with respect to 100 parts by mass of the total amount of the component (A) and the component (B) from the viewpoint of easily reducing an actual measured value of a line width. The content of the hydrogen donor may be 0.1 parts by mass or more, 0.2 parts by mass or more, 0.3 parts by mass or more, 0.4 parts by mass or more, or 0.5 parts by mass or more. The content of the hydrogen donor may be 5 parts by mass or less, 3 parts by mass or less, 2 parts by mass or less, 1.5 parts by mass or less, 1 part by mass or less, 0.8 parts by mass or less, 0.7 parts by mass or less, or 0.5 parts by mass or less. From these viewpoints, the content of the hydrogen donor may be 0.1 to 5 parts by mass.

Examples of the anthracene compound include 9,10-dibutoxyanthracene, 9,10-diphenylanthracene, and 9,10-diethoxyanthracene. The anthracene compound may include 9,10-dibutoxyanthracene from the viewpoint of easily reducing an actual measured value of a line width.

The content of the anthracene compound may be in the following range with respect to 100 parts by mass of the total amount of the component (A) and the component (B) from the viewpoint of easily reducing an actual measured value of a line width. The content of the anthracene compound may be 0.1 parts by mass or more, 0.2 parts by mass or more, 0.3 parts by mass or more, 0.4 parts by mass or more, 0.5 parts by mass or more, 0.6 parts by mass or more, or 0.65 parts by mass or more. The content of the anthracene compound may be 5 parts by mass or less, 3 parts by mass or less, 2 parts by mass or less, 1.5 parts by mass or less, 1 part by mass or less, 0.8 parts by mass or less, or 0.7 parts by mass or less. From these viewpoints, the content of the anthracene compound may be 0.1 to 5 parts by mass.

The polymerization inhibitor suppresses polymerization at an unexposed area at the time of forming a resist pattern and easily improves resolution. Examples of the polymerization inhibitor include t-butylcatechol (for example, 4-t-butylcatechol), hindered amine (for example, 2,2,6,6-tetramethyl-4-hydroxypiperidine-1-oxyl), and 4-hydroxy-2,2,6,6-tetramethylpiperidine-N-oxyl.

The content of the polymerization inhibitor may be in the following range with respect to 100 parts by mass of the total amount of the component (A) and the component (B). The content of the polymerization inhibitor may be 0.001 parts by mass or more, 0.003 parts by mass or more, 0.005 parts by mass or more, 0.01 parts by mass or more, 0.015 parts by mass or more, 0.02 parts by mass or more, or 0.025 parts by mass or more, from the viewpoint of easily obtaining excellent sensitivity and resolution. The content of the polymerization inhibitor may be 0.1 parts by mass or less, 0.05 parts by mass or less, 0.04 parts by mass or less, or 0.03 parts by mass or less, from the viewpoint of easily obtaining excellent sensitivity and adhesiveness. From these viewpoints, the content of the polymerization inhibitor may be 0.001 to 0.1 parts by mass.

Examples of the organic solvent include methanol, ethanol, acetone, methyl ethyl ketone, methyl cellosolve, ethyl cellosolve, toluene, N,N-dimethylformamide, and propylene glycol monomethyl ether.

The photosensitive resin composition of the present embodiment may not contain at least one selected from the group consisting of a benzotriazole compound and an aliphatic diamine compound having 8 to 30 carbon atoms. The content of the benzotriazole compound or the content of the aliphatic diamine compound having 8 to 30 carbon atoms may be 0.001% by mass or less, less than 0.001% by mass, or 0.0001% by mass or less, and may be 0% by mass, on the basis of the total amount of solid contents of the photosensitive resin composition.

### <Photosensitive Element>

A photosensitive element of the present embodiment includes a support and a photosensitive resin layer disposed on the support, and the photosensitive resin layer contains the photosensitive resin composition of the present embodiment. The photosensitive element of the present embodiment may include a protective layer disposed on the photosensitive resin layer. The photosensitive element of the present embodiment may include a cushion layer, an adhesive layer, a light-absorbing layer, a gas barrier layer, or the like. The photosensitive element may be in a sheet form, or may be in the form of a photosensitive element roll being w round around a core into a roll.

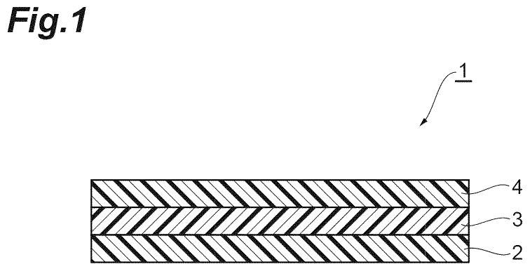

FIG. 1 is a schematic cross-sectional view illustrating an example of a photosensitive element. As illustrated in FIG. 1, a photosensitive element 1 includes a support (support film) 2, a photosensitive resin layer 3 disposed on the support 2, and a protective layer (protective film) 4 disposed on the photosensitive resin layer 3. The photosensitive resin layer 3 is composed of the photosensitive resin composition of the present embodiment.

The photosensitive element 1 can be obtained, for example, by the following procedure. First, the photosensitive resin layer 3 is formed on the support 2. The photosensitive resin layer 3 can be formed, for example, by drying a coating layer formed by applying a photosensitive resin composition containing an organic solvent. Next, the protective layer 4 is disposed on the photosensitive resin layer 3.

Each of the support and the protective layer may be a polymer film having heat resistance and solvent resistance, and may be a polyester film (such as a polyethylene terephthalate film), a polyolefin film (such as a polyethylene film or a polypropylene film), a hydrocarbon-based polymer (excluding a polyolefin film), or the like. The type of the film constituting the protective layer and the type of the film constituting the support may be the same as or different from each other.

The thickness of the support may be 1 μm or more, 5 μm or more, 10 μm or more, or 15 μm or more, from the viewpoint of easily suppressing the damage of the support when the support is peeled off from the photosensitive resin layer. The thickness of the support may be 100 μm or less, 50 μm or less, 30 μm or less, or 20 μm or less, from the viewpoint of suitably performing exposure in the case of exposure through the support. The thickness of the photosensitive resin layer (thickness after drying; in a case where the photosensitive resin composition contains an organic solvent, the thickness after the organic solvent is volatilized) may be the thickness of the above-described film-shaped photosensitive resin composition.

### <Method for Producing Laminate>

A method for producing a laminate of the present embodiment includes a photosensitive resin layer disposing step of disposing a photosensitive resin layer on a base material (for example, a substrate) by using the photosensitive resin composition or photosensitive element of the present embodiment, an exposure step of photo-curing (exposing) a part of the photosensitive resin layer, and a development step of removing an uncured area (unexposed area) of the photosensitive resin layer to form a cured product pattern. A laminate of the present embodiment is obtained by the method for producing a laminate of the present embodiment, and may be a wiring board (for example, a printed circuit board). The laminate of the present embodiment may be an embodiment including a base material and a cured product pattern (cured product of the present embodiment) disposed on the base material.

In the photosensitive resin layer disposing step, a photosensitive resin layer composed of the photosensitive resin composition of the present embodiment is disposed on a base material. For example, the photosensitive resin layer may be formed by applying the photosensitive resin composition onto the base material and drying the photosensitive resin composition, and may be formed by removing the protective layer from the photosensitive element and then pressure-bonding the photosensitive resin layer of the photosensitive element to the base material while heating the photosensitive resin layer.

In the exposure step, a region other than a region of the photosensitive resin layer in which a mask is disposed may be exposed and photo-cured by irradiation with an active light ray in a state where the mask is disposed on the photosensitive resin layer, and a part of the photosensitive resin layer may be exposed and photo-cured by irradiation with an active light ray at a desired pattern by a direct writing exposure method such as an LDI exposure method or a DLP exposure method without using a mask. As the light source for the active light ray, an ultraviolet source or a visible light source may be used and examples thereof include a carbon are lamp, a mercury vapor are lamp, a high-pressure mercury lamp, an ultrahigh pressure mercury lamp, a xenon lamp, a gas laser (such as an argon laser), a solid-state laser (such as a YAG laser), and a semiconductor laser.

The development method in the development step may be, for example, wet development or dry development. The wet development can be performed using a developing solution suitable for the photosensitive resin composition, for example, by methods such as a dip method, a paddle method, a spray method, brushing, slapping, scrubbing, and dipping while shaking. The developing solution is appropriately selected in accordance with the configuration of the photosensitive resin composition, and may be an alkaline developing solution or an organic solvent developing solution.

The alkaline developing solution may be aqueous solutions containing bases such as alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphate such as sodium pyrophosphate and potassium pyrophosphate; borax; sodium metasilicate; tetramethylammonium hydroxide; ethanolamine; ethylenediamine; diethylene triamine; 2-amino-2-hydroxymethyl-1,3-propanediol; 1,3-diamino-2-propanol; and morpholine.

The organic solvent developing solution may contain organic solvents such as 1,1,1-trichloroethane, N-methylpyrrolidone, N,N-dimethylformamide, cyclohexanone, methyl isobutyl ketone, and γ-butyrolactone.

The method for producing a laminate of the present embodiment may include a step of further curing a cured area of the photosensitive resin layer by heating at 60 to 250° C. or exposure at 0.2 to 10 J/cm² after the exposure step and/or after the development step.

The method for producing a laminate of the present embodiment may include a metal layer formation step of forming a metal layer on at least a part of a portion of the base material in which a cured product pattern is not formed, after the development step. The metal layer may be, for example, a metal copper layer. The metal layer can be formed, for example, by performing a plating treatment. The plating treatment may be one or both of an electrolytic plating treatment and a non-electrolytic plating treatment. The laminate of the present embodiment may be an embodiment having a base material, a cured product pattern disposed on the base material, and a metal layer disposed on at least a part of a portion of the base material in which the cured product pattern is not formed.

The method for producing a laminate of the present embodiment may include a step of removing the cured product pattern after the metal layer formation step. The cured product pattern can be removed, for example, using a strong alkaline aqueous solution by performing development such as a dipping method and a spraying method.

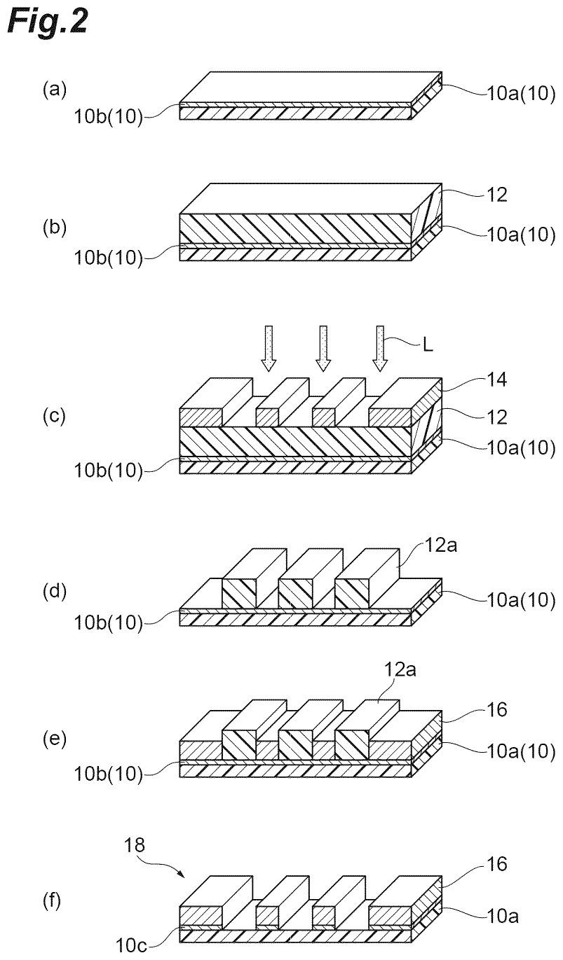

FIG. 2 is a schematic view illustrating an example of a method for producing a laminate (method for producing a wiring board). In the example of the method for producing a laminate, first, as illustrated in FIG. 2(a), a base material (for example, a substrate for circuit formation) 10 having an insulation layer 10a and a conductor layer 10b disposed on the insulation layer 10a is prepared. The conductor layer 10b may be, for example, a metal copper layer.

Next, as illustrated in FIG. 2(b), a photosensitive resin layer 12 is disposed on the conductor layer 10b of the base material 10 (photosensitive resin layer disposing step). In the photosensitive resin layer disposing step, the photosensitive resin layer 12 is disposed on the conductor layer 10b of the base material 10 by using the photosensitive resin composition or photosensitive element of the present embodiment.

Next, as illustrated in FIG. 2(c), a region other than a region of the photosensitive resin layer 12 in which a mask 14 is disposed is exposed and photo-cured by irradiation with an active light ray L in a state where the mask 14 is disposed on the photosensitive resin layer 12.

Next, after the mask 14 is removed, and as illustrated in FIG. 2(d), a region (uncured area) other than the photo-cured area in the photosensitive resin layer is removed from the base material 10 by development to form a resist pattern 12a composed of the photo-cured area (cured product of the photosensitive resin layer).

Next, as illustrated in FIG. 2(e), a wiring layer (metal layer) 16 is formed on a portion of the conductor layer 101b of the base material 10 in which the resist pattern 12a is not formed. The wiring layer 16 may be formed using the same material as that of the conductor layer 10b, and may be formed using a material different from that of the conductor layer 10b.

Next, as illustrated in FIG. 2(f), the resist pattern 12a is removed, and the conductor layer 10b provided at the position corresponding to the resist pattern 12a is removed, thereby forming a conductor layer 10c. Thereby, a wiring board 18 having the conductor layer 10c and the wiring layer 16 disposed on the insulation layer 10a is obtained. The conductor layer 10b can be removed by an etching treatment. An etching solution is appropriately selected in accordance with the type of the conductor layer 10b, and may be, for example, a cupric chloride solution, a ferric chloride solution, an alkali etching solution, a hydrogen peroxide etching solution, or the like.

### EXAMPLES

Hereinafter, the present disclosure will be further specifically described by means of Examples; however, the present disclosure is not limited to these Examples.

### <Synthesis of Binder Polymer>

A solution (a) was prepared by mixing 27 parts by mass of methacrylic acid, 3 parts by mass of 2-hydroxyethyl methacrylate, 20 parts by mass of benzyl methacrylate, 50 parts by mass of styrene, and 0.9 parts by mass of azobisisobutyronitrile. A solution (b) was prepared by dissolving 0.5 parts by mass of azobisisobutyronitrile in 50 parts by mass of a mixed liquid of 30 parts by mass of methyl cellosolve and 20 parts by mass of toluene. After charging 500 g of a mixed liquid of 30 parts by mass of methyl cellosolve and 20 parts by mass of toluene in a flask equipped with a stirrer, a reflux condenser, a thermometer, a dropping funnel, and a nitrogen gas inlet tube, stirring was performed while blowing nitrogen gas into the flask, and the temperature was raised to 80° C. The solution (a) was added dropwise to the above-described flask over 4 hours at a constant dropwise addition rate, and then the solution in the flask was stirred at 80° C. for 2 hours. Next, the solution (b) was added dropwise to the above-described flask over 10 minutes at a constant dropwise addition rate, and then the solution in the flask was stirred at 80° C. for 3 hours. Further, the solution in the flask was heated to 90° C. over 30 minutes, and then kept at 90° C. for 2 hours. Thereafter, stirring was stopped, and the solution was cooled to room temperature (25° C.), thereby obtaining a solution of a binder polymer. The non-volatile content (solid content) of the solution of the binder polymer was 56% by mass.

The acid value of the binder polymer was 176 mgKOH/g. The acid value was measured by the following procedure. First, 1 g of the binder polymer as a measurement target for the acid value was precisely weighed, and then 30 g of acetone was added to the binder polymer for uniformly dissolving, thereby obtaining a solution. Next, an appropriate amount of phenolphthalein as an indicator was added to this solution and then titration was performed using a 0.1 N KOH (potassium hydroxide) aqueous solution. The mass (unit: mg) of KOH necessary for neutralization of the acetone solution of the binder polymer was calculated to determine the acid value.

The weight average molecular weight (Mw) of the binder polymer was 35000, and the number average molecular weight (Mn) thereof was 16000. The weight average molecular weight and the number average molecular weight were measured by gel permeation chromatography (GPC) under the following conditions and were derived by conversion using a calibration curve of standard polystyrene.

### (GPC Conditions)

Pump: Hitachi L-6000 type (manufactured by Hitachi, Ltd., trade name)
Column: Three columns below in total (manufactured by Showa Denko Materials Co., Ltd., trade name)
   Gelpack GL-R440
   Gelpack GL-R450
   Gelpack GL-R400M
Eluent: Tetrahydrofuran
Measurement temperature: 40° C.
Flow rate: 2.05 mL/min
Detector: Hitachi L-3300 type RI (manufactured by Hitachi, Ltd., trade name)

### <Preparation of Photosensitive Resin Composition>

### Example 1

A photosensitive resin composition was prepared by mixing 100 parts by mass of the above-described solution of the binder polymer (binder polymer (non-volatile content): 56 parts by mass), 35 parts by mass of 2,2-bis(4-(methacryloxypentaethoxy)phenyl)propane (EO average 10 mol adduct, molecular weight: 804, manufactured by Showa Denko Materials Co., Ltd., trade name: FA-321M(70)), 5 parts by mass of 2,2-bis(4-(methacryloxypolyethoxy)phenyl)propane (EO average 2.6 mol adduct, molecular weight: 478, manufactured by Kyoeisha Chemical Co., Ltd., trade name: BP-2EM), 4 parts by mass of (PO)(EO)(PO)-modified dimethacrylate (EO average 6 mol and PO average 12 mol adduct (total value), molecular weight: 1114, manufactured by Showa Denko Materials Co., Ltd., trade name: FA-024M), 6 parts by mass of a photopolymerization initiator (2,2′-bis(o-chlorophenyl)-4,4′,5,5′-tetraphenyl-1,2′-biimidazole, BCIM, manufactured by Hampford Research Inc.), 0.5 parts by mass of 5-amino-1H-tetrazole, 0.5 parts by mass of a hydrogen donor (leuco crystal violet, LCV, manufactured by Yamada Chemical Co., Ltd.), 0.65 parts by mass of a sensitizer (9,10-dibutoxyanthracene, DBA, manufactured by Kawasaki Kasei Chemicals Ltd.). 0.015 parts by mass of a polymerization inhibitor A (4-t-butylcatechol, manufactured by DIC Corporation, trade name: DIC-TBC), 0.01 parts by mass of a polymerization inhibitor B (manufactured by Asahi Denka Co., Ltd., trade name: LA-7RD), 0.02 parts by mass of a dye (malachite green, MKG, manufactured by OSAKA ORGANIC CHEMICAL INDUSTRY LTD.), and 1 part by mass of an additive A (light stabilizer, manufactured by Showa Denko Materials Co., Ltd., trade name: FA711MM).

### Example 2

A photosensitive resin composition was prepared in the same manner as in Example 1, except that 0.5 parts by mass of 5-mercaptotetrazole was used instead of 0.5 parts by mass of 5-amino-1H-tetrazole.

### Comparative Example 1

A photosensitive resin composition was prepared in the same manner as in Example 1, except that 0.5 parts by mass of an additive B (mixture of carboxybenzotriazole, 5-amino-1H-tetrazole, and methoxypropanol; manufactured by SANWA KASEI CORP., trade name: SF-808H) was used instead of 0.5 parts by mass of 5-amino-1H-tetrazole. The content of 5-amino-1H-tetrazole in the photosensitive resin composition was 0.003 parts by mass with respect to 100 parts by mass of the total of the binder polymer and the photopolymerizable compound.

### Comparative Example 2

A photosensitive resin composition was prepared in the same manner as in Example 1, except that 0.5 parts by mass of 2-mercaptobenzimidazole was used instead of 0.5 parts by mass of 5-amino-1H-tetrazole.

### <Production of Photosensitive Element>

A polyethylene terephthalate film (manufactured by Toray Industries, Inc., trade name “FS-31”) having a thickness of 16 μm was prepared as the support. The above-described photosensitive resin composition was applied onto the support to have an uniform thickness and then sequentially dried with a hot air convection drier set at 80 and 120° C. to form a photosensitive resin layer (photosensitive film, thickness after drying: 25 μm). A polyethylene film (manufactured by TAMAPOLY CO., LTD., trade name “NF-15”) as the protective layer was attached onto this photosensitive resin layer, thereby obtaining a photosensitive element having the support, the photosensitive resin layer, and the protective layer in this order.

### <Production of Laminate>

A copper-clad laminate plate (substrate, manufactured by Showa Denko Materials Co., Ltd., trade name: MCL-E-67) having copper foils (thickness: 35 μm) disposed on both surfaces of a glass epoxy material was pickled, rinsed, and then dried with an air stream. Next, the copper-clad laminate plate was heated to 80° C., and then the above-described photosensitive element was laminated so that the photosensitive resin layer was in contact with the copper surface while the protective layer was peeled off, thereby obtaining a laminate having the copper-clad laminate plate, the photosensitive resin layer, and the support in this order. The lamination was performed using a heat roll set at 110° C. at a pressure-bonding pressure of 0.4 MPa and at a roll speed of 1.0 m/min.

### <Evaluation: Adhesiveness>

After a 41-step tablet (manufactured by Showa Denko Materials Co., Ltd.) was placed on the support of the above-described laminate, the photosensitive resin layer was exposed (drawn) through the support at an exposure dose (irradiation energy (lose) for 15 steps remaining on the 41-step tablet after the development by a direct writing exposure machine (manufactured by Via Mechanics, Ltd., trade name: DE-1UH) employing a blue-violet laser diode with a wavelength of 405 nm as the light source using a drawing pattern with an L/S of x/3× (x=1 to 20, unit: μm, interval: 1 μm) (pattern in which a region of “L/S=x/3×” and a region of “L/S=(x+1)/3(x+1)” are sequentially arranged; each region has a plurality of line areas and space areas, line widths are the same as each other, and space widths are the same as each other).

After exposure, the support was peeled off from the laminate to expose the photosensitive resin layer. Next, 1.0% by mass of a sodium carbonate aqueous solution was sprayed to the photosensitive resin layer at 30° C. for twice the time of the minimum developing time to remove the unexposed area. After the development, the minimum value was obtained among the line width values of resist patterns in which removal of space areas (unexposed areas) without residues and formation of line areas (exposed areas) without meandering and chipping were determined by microscopic observation (trade name: VHX-1000 manufactured by KEYENCE CORPORATION). Next, for the line area of the region providing the minimum value of this line width, the line widths of three adjacent line areas (widths of top portions of the line areas) were measured, and an average value (unit: μm) of the line widths was obtained. Results are shown in Table 1. A smaller numerical value indicates more satisfactory adhesiveness.

The above-described minimum developing time was evaluated in advance by the following procedure. First, the above-described laminate was cut into a rectangular shape (12.5 cm×4 cm) and then the support was peeled off thereby obtaining a test specimen. Then, an unexposed photosensitive resin layer in the test specimen was spray-developed at a pressure of 0.18 MPa using 1.0% by mass of a sodium carbonate aqueous solution set at 30° C., and the shortest time that allowed the complete removal of the unexposed photosensitive resin layer to be visually confirmed was obtained as a minimum developing time (MD).

TABLE 1

| | | | Comparative | |
|---|---|---|---|---|
| | Example | | Example | |
| | 1 | 2 | 1 | 2 |
| Content [parts by mass] | 0.5 | 0.5 | 0.003 | 0 |
| of tetrazole compound | | | | |
| Adhesiveness [μm] | 5.50 | 5.70 | 7.77 | 9.50 |

### REFERENCE SIGNS LIST

1: photosensitive element, 2: support, 3, 12: photosensitive resin layer, 4: protective layer, 10: base material, 10a: insulation layer, 10b, 10c: conductor layer, 12a: resist pattern, 14: mask, 16: wiring layer, 18: wiring board, L: active light ray.

1. A photosensitive resin composition comprising: a binder polymer; a photopolymerizable compound; a photopolymerization initiator; and a tetrazole compound, wherein
a content of a monomer unit of a styrene compound in the binder polymer is more than 30% by mass, and
a content of the tetrazole compound is 0.01 parts by mass or more with respect to 100 parts by mass of a total of the binder polymer and the photopolymerizable compound.

2. The photosensitive resin composition according to claim 1, wherein the content of the tetrazole compound is 0.01 to 1 part by mass with respect to 100 parts by mass of the total of the binder polymer and the photopolymerizable compound.

3. The photosensitive resin composition according to claim 1, wherein the tetrazole compound includes 5-amino-1H-tetrazole.

4. The photosensitive resin composition according to claim 1, wherein the tetrazole compound includes 5-mercaptotetrazole.

5. The photosensitive resin composition according to claim 1, wherein a weight average molecular weight of the binder polymer is 30000 to 40000.

6. The photosensitive resin composition according to claim 1, wherein the photopolymerizable compound includes a bisphenol A-type (meth)acrylic acid compound.

7. The photosensitive resin composition according to claim 1, which is film-shaped.

8. The photosensitive resin composition according to claim 7, wherein a thickness is 30 μm or less.

9. A photosensitive element comprising: a support; and a photosensitive resin layer disposed on the support, wherein
the photosensitive resin layer contains the photosensitive resin composition according to claim 1.

10. A method for producing a laminate, the method comprising:
a step of disposing a photosensitive resin layer on a base material by using the photosensitive resin composition according to claim 1;
a step of photo-curing a part of the photosensitive resin layer; and
a step of removing an uncured area of the photosensitive resin layer to form a cured product pattern.

11. A method for producing a laminate, the method comprising:
a step of disposing a photosensitive resin layer on a base material by using the photosensitive element according to claim 9;
a step of photo-curing a part of the photosensitive resin layer; and
a step of removing an uncured area of the photosensitive resin layer to form a cured product pattern.

12. The photosensitive resin composition according to claim 1, wherein the binder polymer has a (meth)acrylic acid as a monomer unit.

13. The photosensitive resin composition according to claim 1, wherein the binder polymer has hydroxyalkyl (meth)acrylate as a monomer unit.

14. The photosensitive resin composition according to claim 13, wherein a content of the monomer unit of the hydroxyalkyl (meth)acrylate is 0.1 to 20% by mass on the basis of a total amount of monomer units constituting the binder polymer.

15. The photosensitive resin composition according to claim 1, wherein the binder polymer has aryl (meth)acrylate as a monomer unit.

16. The photosensitive resin composition according to claim 15, wherein a content of the monomer unit of the aryl (meth)acrylate is 1 to 50% by mass on the basis of a total amount of monomer units constituting the binder polymer.

17. The photosensitive resin composition according to claim 1, wherein the binder polymer has benzyl (meth)acrylate as a monomer unit.

18. The photosensitive resin composition according to claim 1, wherein the photopolymerizable compound includes a bisphenol A-type (meth)acrylic acid compound.

19. The photosensitive resin composition according to claim 18, wherein a content of the bisphenol A-type (meth)acrylic acid compound is 60 to 100% by mass on the basis of a total mass of the photopolymerizable compound.

20. The photosensitive resin composition according to claim 18, wherein a content of the bisphenol A-type (meth)acrylic acid compound is 15 to 90 parts by mass with respect to 100 parts by mass of a total amount of the binder polymer and the photopolymerizable compound.
